(19) United States
(12) Patent Application Publication
(10) Pub. No.: US 2006/0154480 A1
(43) Pub. Date: Jul. 13, 2006

(54) Vaporizer for cvd, solution voporizing cvd system and voporization method for cvd

(76) Inventor: Hisayoshi Yamoto, Nagareyama-shi (JP)

Correspondence Address: QUARLES & BRADY LLP, 411 E. WISCONSIN AVENUE, SUITE 2040, MILWAUKEE, WI, 53202-4497, US

(21) Appl. No.: 10/526,786

(22) PCT Filed: May 17, 2004
(86) PCT No.: PCT/JP04/06635

§ 371 Date: Mar. 4, 2005

(30) Foreign Application Priority Data
Dec. 26, 2003 (JP) 2003-432600

(51) Int. Cl. H01L 21/44; C23C 16/00

(52) U.S. Cl. 438/680; 118/715

(57) ABSTRACT

The vaporizer for CVD of the present invention comprises: the pipes for the plurality of raw-material solutions, each pipe supplying the plurality of raw-material solutions separately from one another; the pipe for the carrier gas provided in a manner covering outwards of the pipes for the raw-material solutions, the pipe 3 allowing the pressurized carrier gas to flow thereinside and the outwards of the pipes for the raw-material solutions; the orifice provided on a leading end of the pipe for the carrier gas, the orifice being spaced away from leading ends of the pipes for the raw-materials solutions; the vaporizing tube connected to the leading end of the pipe for the carrier gas, the vaporizing tube being connected to the inside of the pipe for the carrier gas via the orifice; the cleaning mechanism cleaning at least one among the leading end of the pipe for the carrier gas, the orifice, and the vaporizing tube; and a heating means for heating the vaporizing tube.

### BACKGROUND OF THE INVENTION

1. Field of the Invention

The present invention relates to a vaporizer for CVD (Chemical Vapor Deposition), a solution-vaporization type CVD apparatus and a vaporization method for CVD. In particular, the present invention relates to a vaporizer for CVD, a vaporization method for CVD and a solution-vaporization type CVD apparatus including the vaporizer which can suppress a clogging at a solution pipe etc., for extending continuous operation times thereof.

2. Description of the Related Art

In a technique of CVD applied to semiconductor industry from around 1970, when forming a thin film, a reactant in gas state is introduced into a reactor, allowed to react, and thus a thin film of various compositions is formed on a semiconductor substrate made of, for instance, silicon. With respect to the CVD technique, however, there is a technical limitation that a thin film can not be formed by CVD unless a gas reactant is prepared.

At IEDM (International Electron Devices Meeting) of 1987, W. I. KINNEY et al. announced a technique for fabricating a ferroelectric memory FeRAM (FRAM: Ferroelectric Random Access Memory) by utilizing a polarization phenomenon of a ferroelectric material such as PZT, SBT. At that time, a thin film of a ferroelectric material such as PZT, SBT could not be formed by CVD because it was technically difficult to prepare a chemical in a gas state containing Zr, Sr, Bi or the like. Accordingly, a solution coating process, similar to one for forming a photo resist was applied to the fabrication of a FeRAM. A ferroelectric thin film (thickness: 400-300 nm) formed by the solution coating process, however, has poor step coverage. Moreover, when it is thinned (thickness: 150-40 nm), the number of pin holes are increased, whereby electrical isolation thereof is decreased. Because a FeRAM-LSI has a plurality of steps and requires the thinning of a ferroelectric material (thickness: 100-50 nm), it is necessary that a high-quality ferroelectric thin film be formed by CVD in order to attempt to put a FeRAM-LSI to practical use.

In 1992, Dr. Shiozaki, an assistant professor in the engineering Dept. at Kyoto University, formed a ferroelectric thin film PZT by CVD and announced this formation at an academic conference. A CVD apparatus used by Dr. Shiozaki adopted a technique for vaporizing (gasifying) a solid chemical by sublimation.

In the technique for gasifying a solid chemical by sublimation, however, it is difficult to increase a flow rate of a reactant because a rate of sublimation when sublimating a solid chemical is low. Moreover, because of the difficulty of the controlling the flow rate of the reactant, a deposition rate of a thin film is low, thus resulting in a poor reproducibility. Further, it is difficult to carry the sublimated chemical to a reactor with a pipe heated at approximately 250° C.

In order to make an additional experiment on the technique announced by Dr. Shiozaki, the inventor of the present invention purchased the same CVD apparatus used by Dr. Shiozaki from the same manufacturer with Dr. Shiozaki's assistance, and performed a film-forming experiment. Immediately after starting an operation of the CVD apparatus, however, a high-temperature pipe was clogged. After fixed, the high-temperature pipe was then heated extraordinary. Based on his experience like this, he concluded that a technique for evenly heating thin, long stainless-made pipes (external diameter: ¼ inch and length: 1 m of several pipes) with a plurality of valves on middle portions thereof at 250±5° C. is an extremely difficult technique.

Based on the above-described experience, he reached to a thought that it is difficult to put the sublimation-type CVD apparatus to practical use. Consequently, he successfully deposited a high-quality thin film of a ferroelectric material SBT by solution-vaporization CVD (so-called “flash CVD”). He announced it at an international academic conference, ISIF '96 (“Performance of SrBi₂Ta₂O₉ Thin Films Grown by Chemical Vapor Deposition for Nonvolatile Memory Applications”. C. Isobe, H. Yamoto, H. Yagi et al. 9^{th} International Symposium on Integrated Ferroelectrics. March, 1996), and verified the possibility of the commercialization of a ferroelectric memory FeRAM.

As a vaporizer for producing a reaction gas for SBT-thin-film-formation by dissolving solid material in solvent so as to produce solution, and allowing the solution to gasify at high temperature, one made by ATMI Inc. was initially adopted. This vaporizer, however, was not adopted by a CVD apparatus of mass production type because it was clogged in a matter of ten hours. Consequently, in 1996, the inventor of the present invention Mr. Yoshioka of Shimadzu Corporation and Dr. Toda, a professor of Material Engineering dept. of Faculty of Engineering at Yamagata University to develop and manufacture a high-performance solution supplying system and a vaporizer necessary for stably depositing a high-quality SBT thin film. An apparatus (the solution supplying system and vaporizer) delivered to him, however, had the following technical problem, and thus it was difficult to stably deposit a SBT thin film. Meanwhile, this apparatus is disclosed by Japanese Unexamined Patent Publications No. 2000-216150 and No. 2002-105646.

As a reactant for synthesizing a SBT thin film, Sr(DPM)₂, BiPh₃, Ta(OEt)₅, Sr[Ta(OEt)₅(OC₂H₄OMe)]₂, Bi(OtAm)₃, Bi(MMP)₃, etc. are used particularly, when Sr[Ta(OEt)₅(OC₂H₄OMe)]₂+Bi(MMP)₃ is used, a high-speed deposition (5-100 nm/min) at 320-420° C. can be performed, whereby a high-quality SBT thin film having good step coverage and electrical property can be formed. The above apparatus, however, was clogged immediately when Sr[Ta(OEt)₅(OC₂H₄OMe)]₂+Bi(MMP)₃ was used as a reactive gas. The inventor of the present invention researched and examined the reason thereof, and found that when solutions of Sr[Ta(OEt)₅(OC₂H₄OMe)]₂ and Bi(MMP)₃ were mixed at room temperature, Sr[Ta(OEt)₅(OC₂H₄OMe)]₂ and Bi(MMP)₃ reacted with each other, a material having a small solubility and not easily subliming was synthesized by the reaction, and thus a path for allowing the solutions to flow and a leading end of a vaporizing tube were clogged. This phenomenon will now be explained in detail.

FIG. 11 is a TG CHART (Ar 760/10 Torr, O₂ 760 Toor) of Sr[Ta(OEt)₅(OC₂H₄OMe)]₂. This figure illustrates: a graph 101 representing changes in a weight of a sample of Sr[Ta(OEt)₅(OC₂H₄OMe)]₂ when the sample is subject to a temperature rising from 30 to 600° C. at a rate of 10° C./min. under argon atmosphere at a pressure of 760 Torr and a flow rate of 100 ml/min.; a graph 102 representing changes in a weight of the sample when it is subject to a temperature rising from 30 to 600° C. at a rate of 10° C./min. under argon atmosphere at a pressure of 10 Torr and a flow rate of 50 ml/min.; and a graph 103 representing changes in a weight of the sample when it is subject to a temperature rising from 30 to 600° C. at a rate of 10° C./min. under oxygen atmosphere at a pressure of 760 Torr and a flow rate of 100 ml/min. As is illustrated in the figure, Sr[Ta(OEt)₅(OC₂H₄OMe)]₂ completely sublimes at approximately 220° C. under argon atmosphere at a pressure of 10 Torr.

FIG. 12 is a TG CHART (Ar 760/10 Torr, O₂ 760 Toor) of Bi(OtAm)₃. This figure illustrates: a graph 111 representing changes in a weight of a sample of Bi(OtAm)₃ when the sample is subject to a temperature rising from 30 to 600° C. at a rate of 10° C./min. under argon atmosphere at a pressure of 760 Torr and a flow rate of 100 ml/min.; a graph 112 representing changes in a weight of the sample when it is subject to a temperature rising from 30 to 600° C. at a rate of 10° C./min. under argon atmosphere at a pressure of 10 Torr and a flow rate of 50 ml/min.; and a graph 113 representing changes in a weight of the sample when it is subject to a temperature rising from 30 to 600° C. at a rate of 10° C./min. under oxygen atmosphere at a pressure of 760 Torr and a flow rate of 100 ml/min. As illustrated, approximately 98% of Bi(OtAm)₃ sublimes at approximately 130° C. under argon atmosphere at a pressure of 10 Torr.

FIG. 13 is a TG CHART (Ar 760/10 Torr, O₂ 760 Toor) of Bi(MMP)₃. This figure illustrates: a graph 121 representing changes in a weight of a sample of Bi(MMP)₃ when the sample is subject to a temperature rising from 30 to 600° C. at a rate of 10° C./min. under argon atmosphere at a pressure of 760 Torr and a flow rate of 100 ml/min.; a graph 122 representing changes in a weight of the sample when it is subject to a temperature rising from 30 to 600° C. at a rate of 10° C./min. under argon atmosphere at a pressure of 10 Torr and a flow rate of 50 ml/min.; and a graph 123 representing changes in a weight of the sample when it is subject to a temperature rising from 30 to 600° C. at a rate of 10° C./min. under oxygen atmosphere at a pressure of 760 Torr and a flow rate of 100 ml/min. As illustrated, Bi(MMP)₃ completely sublimes at approximately 150° C. under argon atmosphere at a pressure of 10 Torr.

FIG. 14 is a TG CHART (Ar 760/10 Torr, O₂ 760 Toor) of a mixture of Bi(OtAm)₃/Sr[Ta(OEt)₆]₂. This figure illustrates: a graph 131 representing changes in a weight of a sample of Bi(OtAm)₃/Sr[Ta(OEt)₆]₂ when the sample is subject to a temperature rising from 30 to 600° C. at a rate of 10° C./min. under argon atmosphere at a pressure of 760 Torr and a flow rate of 100 ml/min.; and a graph 133 representing changes in a weight of the sample when it is subject to a temperature rising from 30 to 600° C. at a rate of 10° C./min. under oxygen atmosphere at a pressure of 760 Torr and a flow rate of 100 ml/min. As illustrated, only 80% of the mixture of Bi(OtAm)₃/Sr[Ta(OEt)₆]₂ sublimes under argon atmosphere even if it is heated at greater than or equal to 300° C.

As explained, both Sr[Ta(OEt)₅(OC₂H₄OMe)]₂ and Bi(OtAm)₃ almost completely sublime in individuals, but when mixed with each other, part of them do not sublime. A deterioration of the sublimation characteristic thereof may cause the clogging of the vaporizer.

A reason for the deterioration of the sublimation characteristic can be explained with NMR characteristic (Nuclear Magnetic Resonance of H) as illustrated in FIG. 15. When Bi(OtAm)₃ and Sr[Ta(OEt)₆]₂ are mixed, a new NMR characteristic is observed. This represents that a new chemical compound is formed and resides.

FIG. 16 is a TG CHART (Ar 760/10 Torr, O₂ 760 Toor) of a mixture of Bi(MMP)₃/Sr[Ta(OEt)₅(OC₂H₄OMe)]₂. This figure illustrates a graph representing changes in a weight of a sample of Bi(MMP)₃/Sr[Ta(OEt)₅(OC₂H₄OMe)]₂ when the sample is subject to a temperature rising from 30 to 600° C. at a rate of 10° C./min. under argon atmosphere at a pressure of 760 Torr and a flow rate of 100 ml/min. As illustrated, only 80% of the mixture of Bi(MMP)₃/Sr[Ta(OEt)₅(OC₂H₄OMe)]₂ sublimes under argon atmosphere.

FIG. 17 is a TG CHART (Ar 760/10 Torr, O₂ 760 Toor) of BiPh₃. This figure illustrates: a graph 141 representing changes in a weight of a sample of BiPh₃ when the sample is subject to a temperature rising from 30 to 600° C. at a rate of 10° C./min. under argon atmosphere at a pressure of 760 Torr and a flow rate of 100 ml/min.; a graph 142 representing changes in a weight of the sample when it is subject to a temperature rising from 30 to 600° C. at a rate of 10° C./min. under argon atmosphere at a pressure of 10 Torr and a flow rate of 50 ml/min.; and a graph 143 representing changes in a weight of the sample when it is subject to a temperature rising from 30 to 600° C. at a rate of 10° C./min. under oxygen atmosphere at a pressure of 760 Torr and a flow rate of 100 ml/min. As illustrated, 100% of BiPh₃ sublimes at approximately 200° C.

FIG. 18 is a TG CHART (Ar 760/10 Torr, O₂ 760 Toor) of BiPh₃/Sr[Ta(OEt)₆]₂. This figure illustrates: a graph 151 representing changes in a weight of a sample of BiPh₃/Sr[Ta(OEt)₆]₂ when the sample is subject to a temperature rising from 30 to 600° C. at a rate of 10° C./min. under argon atmosphere at a pressure of 760 Torr and a flow rate of 100 ml/min.; and a graph 153 representing changes in a weight of the sample when it is subject to a temperature rising from 30 to 600° C. at a rate of 10° C./min. under oxygen atmosphere at a pressure of 760 Torr and a flow rate of 100 ml/min. As illustrated, almost 100% of BiPh₃/Sr[Ta(OEt)₆]₂ sublimes at approximately 280° C.

FIG. 19 illustrates NMR characteristics representing stability of mixing BiPh₃ and Sr[Ta(OEt)₆]₂. No synthesis of a new material is observed in a mixture of BiPh₃/Sr[Ta(OEt)₆]₂.

FIG. 20 is a TG-DTA CHART (O₂ 760 Torr) of BiPh₃. As illustrated, an oxidation reaction of BiPh₃ occurs at 465° C. The oxidizing temperature of BiPh₃ is so high with respect to 259° C. of Sr[Ta(OEt)₅(OC₂H₄OMe)]₂, 209° C. of Bi(MMP)₃, and 205° C. of Bi(OtAm)₃, it is thus difficult to use BiPh₃.

Bi(OtAm)₃ causes a hydrolysis reaction with only 180 ppm of moisture. This means that Bi(OtAm)₃ is remarkably more sensitive to moisture than Sr[Ta(OEt)₅(OC₂H₄OMe)]₂ causing a hydrolysis reaction with 1650 ppm of moisture, and Bi(MMP)₃ causing that reaction with 170 ppm of moisture, and thus the treatment of Bi(OtAm)₃ is difficult. Since moisture certainly exists, Bi(OtAm)₃ may be allowed to react with moisture to form Bi oxide, while a possibility that a pipe, a flow meter, etc. are clogged by the formed Bi oxide may increase.

The problems described above can be summarized as follows.

In the technique for vaporizing a solid chemical by sublimation at a room temperature and for using this gas as a reactive gas, a deposition rate of thin film is low and varies, whereby it may be difficult to put it in practical use.

In contrast, in the solution-vaporization CVD using a solid chemical at a room temperature, dissolving the solid chemical in a solvent, atomizing it, and then vaporizing it at high temperature, a deposition rate of thin film is high. In this technique, however, there is a phenomenon that a chemical reaction occurs in a solution state, and thus a solution pipe or the like is clogged. When the solution-pipe or the like is clogged, the CVD apparatus can be continuously operated for short times. Therefore, it is necessary that a solution supplying system be devised.

The present invention has been made to solve the above problems. It is, accordingly, an object of the present invention to provide a vaporizer for CVD, a solution-vaporization type CVD apparatus, and a vaporization method for CVD which can suppress a clogging at a solution pipe etc., so as to extend continuous operation times thereof.

### SUMMARY OF THE INVENTION

In order to attain the above object, according to a first aspect of the present invention, there is provided a vaporizer for CVD which comprises: a dispersing portion dispersing a plurality of raw-material solutions in a carrier gas in fine particulate or misty forms; a plurality of paths for the plurality of raw-material solutions, each of the plurality of paths supplying the plurality of raw-material solutions to the dispersing portion separately from one another; a path for the carrier gas, the path supplying the carrier gas to the dispersing portion separately from the plurality of raw-material solutions; a vaporizing member vaporizing the plurality of raw-material solutions dispersed by the dispersing portion; an orifice connected to the vaporizing member and the dispersing portion, the orifice introducing the plurality of raw-material solutions dispersed by the dispersing portion into the vaporizing member; and a cleaning mechanism cleaning at least one of the dispersing portion, the orifice and the vaporizing member.

According to the above-described vaporizer, since it has the cleaning mechanism, at least one of followings can be cleaned: the dispersing portion; the orifice; and the vaporizing member. When the vaporization of the plurality of raw-material solutions are continuously carried out, solutes of the raw-material solutions gradually precipitate on at least one of the dispersing portion, the orifice and the vaporizing tube, and thus the orifice is gradually clogged. However, by cleaning at least one of them, the clogging can be eliminated.

Alternatively, the above described vaporizer may further comprise a monitoring mechanism for monitoring a pressure of the carrier gas. By observing the pressure thereof with the monitoring mechanism, the condition of the clogging of the orifice can be observed. Accordingly a proper timing for cleaning at least one of the dispersing portion, the orifice and the vaporizing tube can be determined.

In order to attain the above object, according to a second aspect of the present invention, there is provided a vaporizer for CVD which comprises: a dispersing portion dispersing a plurality of raw-material solutions in a carrier gas in fine particulate or misty forms; a plurality of paths for the plurality of raw-material solutions, each of the plurality of paths supplying the plurality of raw-material solutions to the dispersing portion separately from one another; a path for the carrier gas, the path supplying the carrier gas to the dispersing portion separately from the plurality of raw-material solutions; a monitoring mechanism for monitoring a pressure of the carrier gas; a vaporizing member vaporizing the plurality of raw-material solutions dispersed by the dispersing portion; and an orifice connected to the vaporizing member and the dispersing portion, the orifice introducing the plurality of raw-material solutions dispersed by the dispersing portion into the vaporizing member.

In the above-described vaporizer, it is preferable that the dispersing portion be arranged in between the orifice and respective leading ends of the plurality of paths, and the orifice have a smaller diameter than those of the plurality of the paths and the path for the carrier gas.

Moreover, in the above-described vaporizer, it is preferable that the vaporizing member be brought into a reduced pressure state and the dispersing portion be brought into an increased pressure state when the plurality of raw-material solutions vaporized.

In order to attain the above object, according to a third aspect of the present invention, there is provided a vaporizer for CVD which comprises: a plurality of pipes for a plurality of raw-material solutions, each of the plurality of pipes supplying the plurality of raw-material solutions separately from one another; a pipe for a carrier gas, the pipe being provided in a manner covering outwards of the plurality of pipes, while the pipe allowing the pressurized carrier gas to flow thereinside and the outward of each of the plurality of pipes; an orifice provided on a leading end of the pipe for the carrier gas, the orifice being spaced away from leading ends of the plurality of pipes for the plurality of raw-material solutions; a vaporizing tube connected to the leading end of the pipe for the carrier gas, the vaporizing tube being connected to the inside of the pipe for the carrier gas via the orifice; a cleaning mechanism cleaning at least one the leading end of the pipe for the carrier gas, the orifice, the vaporizing tube and a heating means for heating the vaporizing tube.

According to the above-described vaporizer, since it has the cleaning mechanism, at least one of the followings can be cleaned: the leading end of the pipe for the carrier gas; the orifice; and the vaporizing tube. When the vaporization of the plurality of raw-material solutions are continuously carried out, solutes of the raw-material solutions gradually precipitate on at least one of the leading end of the pipe for the carrier gas, the orifice and the vaporization tube, and thus the orifice is gradually clogged. However, by cleaning at least one of them, the clogging can be eliminated.

Alternatively, the above-described vaporizer may further comprise a monitoring mechanism for monitoring a pressure of the carrier gas in the inside of the pipe for the carrier gas. By observing the pressure thereof with the monitoring mechanism, the condition of the clogging of the orifice can be observed. Accordingly a proper timing for cleaning can be determined.

Moreover, in the above-described vaporizer, the cleaning mechanism may clean the leading end of the pipe for the carrier gas and the orifice by supplying at least one solution thereto.

In the above-described vaporizer, the carrier gas and the plurality of raw-material solutions are mixed in between the orifice in the pipe for the carrier gas and respective leading ends of the plurality of pipes, the plurality of raw-material solutions are dispersed in the carrier gas in fine particulate or misty forms, the plurality of dispersed raw-material solutions in fine particulate or misty forms are introduced into the vaporizing tube via the orifice and heated by the heater so as to be vaporized. Accordingly, it is suppressed that only the solvents of the plurality of raw-material solutions vaporize at the orifice and the vaporizing tube adjacent to the orifice, and thus the chemical reaction of the plurality of raw-material solutions can be suppressed, whereby the clogging can be suppressed.

In the above-described vaporizer, it is preferable that the orifice have a smaller diameter than those of the plurality of the pipes and the pipe for the carrier gas.

Moreover, in the above-described vaporizer, the plurality of raw-material solutions can be one made by mixing Sr[Ta(OEt)₅(OC₂H₄OMe)]₂ and a solvent, and one made by mixing Bi(MMP)₃ and a solvent, while the carrier gas can be argon or nitrogen gas.

In order to attain the above object, according to a fourth aspect of the present invention, there is provided a solution-vaporization CVD apparatus which comprises one of the above-identified vaporizer for CVD.

In order to attain the above object, according to a fifth aspect of the present invention, there is provided a solution-vaporization CVD apparatus which comprises at least one vaporizer for CVD above described, and a reaction chamber being connected to the vaporizer, wherein a deposition is carried out with the plurality of raw-material solutions used, the plurality of raw-material solutions being vaporized by the vaporizing tube.

Alternatively, in the above-described solution-vaporization CVD apparatus, it may be equipped with the plurality of vaporizers for CVD; some of the plurality of vaporizers for CVD may be respectively in a cleaned condition cleaned by the cleaning mechanism, while others thereof may be respectively in operated condition; and the plurality of vaporized raw-material solutions may be continuously supplied to the reaction chamber by swapping the plurality of vaporizers for CVD in the operated conditions for those in the cleaned conditions as time advances.

In order to attain the above object, according to a sixth aspect, there is provided a vaporization method for CVD which comprises processes of: supplying a plurality of raw-material solutions and a carrier gas to a dispersing portion separately from one another; mixing the plurality of raw-material solutions and the carrier gas by the dispersing portion and dispersing the plurality of raw-material solutions in the carrier gas in fine particulate or misty forms; vaporizing the raw-material solutions by adiabatic expansion immediately after dispersing; and cleaning at least one of the dispersing portion and an area for vaporizing the raw-material solutions.

In order to attain the above object, according to a seventh aspect of the present invention, there is provided a vaporization method for CVD which comprises processes of: supplying a plurality of raw-material solutions and a carrier gas to a dispersing portion separately from one another; mixing the plurality of raw-material solutions and the carrier gas by the dispersing portion, and dispersing the plurality of raw-material solutions in the carrier gas in fine particulate or misty forms; vaporizing the raw-material solutions by adiabatic expansion immediately after dispersing; observing a pressure of the carrier gas while vaporizing the raw-material solutions, and terminating the supply of the raw-material solutions to the dispersing portion upon observing that the pressure of the carrier gas exceeds a predetermined value; and cleaning at least one of the dispersing portion and an area for vaporizing the plurality of raw-material solutions.

Alternatively, in the above-described vaporization method for CVD, the process for cleaning may be one for cleaning at least one of the dispersing portion and the area for vaporizing the plurality of raw-material solutions by supplying a solvent and the carrier gas thereto; and the pressure of the carrier gas may be monitored during the process for cleaning so that the supply of the solvent is terminated upon observing that the pressure of the carrier gas is turned less than or equal to the predetermined value so as to terminate the process for cleaning.

Moreover, in the above-described vaporization method for CVD, the solvent for cleaning and solvents contained in the plurality of raw-material solutions may be homogeneous.

Further, in the above-described vaporization method for CVD, the solvent for cleaning may be one or a mixture of those selected from a group consisting of ethyl cyclohexane, n-hexane, benzene, toluene, octane, or decane.

According to the present invention, there are provided a vaporizer for CVD, a solution-vaporization CVD apparatus, and a vaporization method for CVD which can suppress a clogging at a solution-pipe etc., so as to extend continuous operation times thereof.

### BRIEF DESCRIPTION OF THE DRAWINGS

FIG. 1A is a schematic view illustrating a structure of a solution supplying system included in a vaporizer for CVD according to a first embodiment of the present, invention, while FIG. 1B is a schematic cross sectional view illustrating the solution supplying system of the vaporizer, a dispersing portion thereof, and a vaporizing member thereof;

FIG. 2C is a schematic view illustrating a structure of a solution supplying system included in a vaporizer for CVD according to a second embodiment of the present invention, while FIG. 2D is a schematic view illustrating a structure of a solution supplying system included in a vaporizer for CVD according to a third embodiment of the present invention;

FIG. 3 is a view illustrating an experimental result that pressures of a carrier gas were monitored;

FIG. 4 is a view illustrating an experimental result that pressures of a carrier gas were monitored;

FIG. 5 is a view illustrating an experimental result that pressures of a carrier gas were monitored;

FIG. 6 is a view illustrating an experimental result that pressures of a carrier gas were monitored;

FIG. 7 is a view illustrating an experimental result that pressures of a carrier gas were monitored;

FIG. 8 is a view illustrating an experimental result that pressures of a carrier gas were monitored;

FIG. 9 is a view illustrating a result of an experiment of reproducibility of SBT-CVD with the vaporizer according to the first embodiment;

FIG. 10 is a view illustrating the result of the experiment of reproducibility of SBT-CVD with the vaporizer according to the first embodiment;

FIG. 11 is a TG CHART (Ar 760/10 Torr, O₂ 760 Toor) of Sr[Ta(OEt)₅(OC₂H₄OMe)]₂;

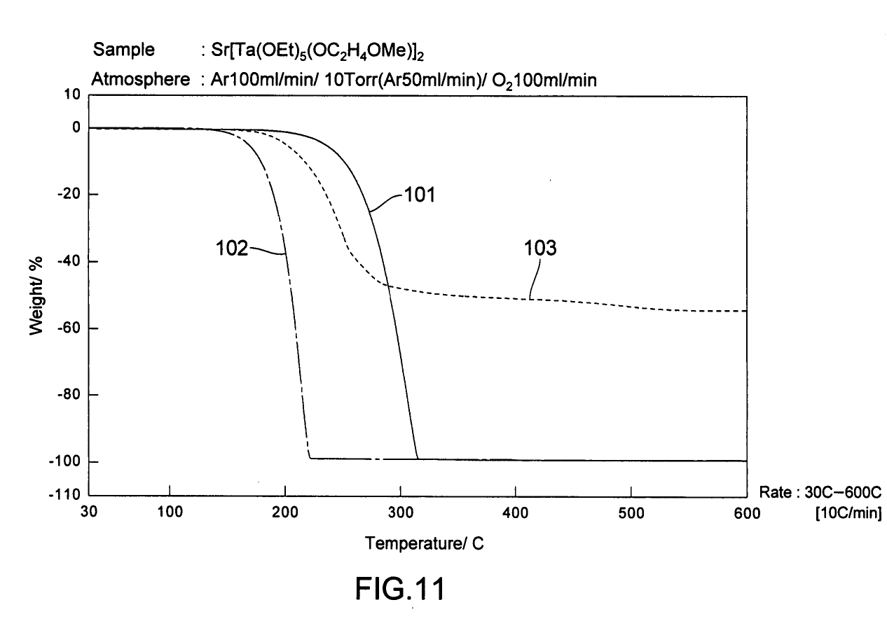

FIG. 12 is a TG CHART (Ar 760/10 Torr, O₂ 760 Toor) of Bi(OtAm)₃;

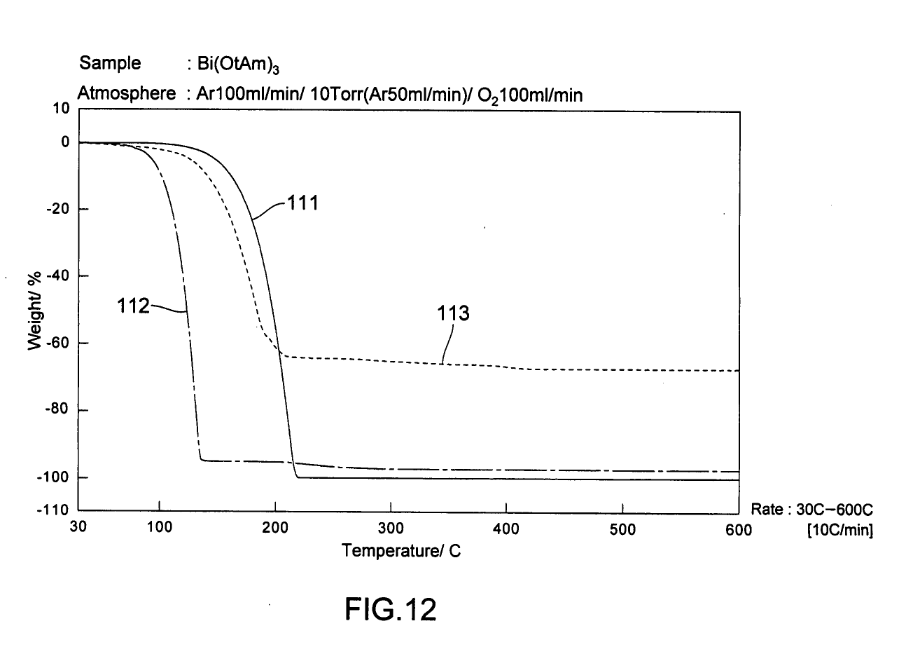

FIG. 13 is a TG CHART (Ar 760/10 Torr, O₂ 760 Toor) of Bi(MMP)₃;

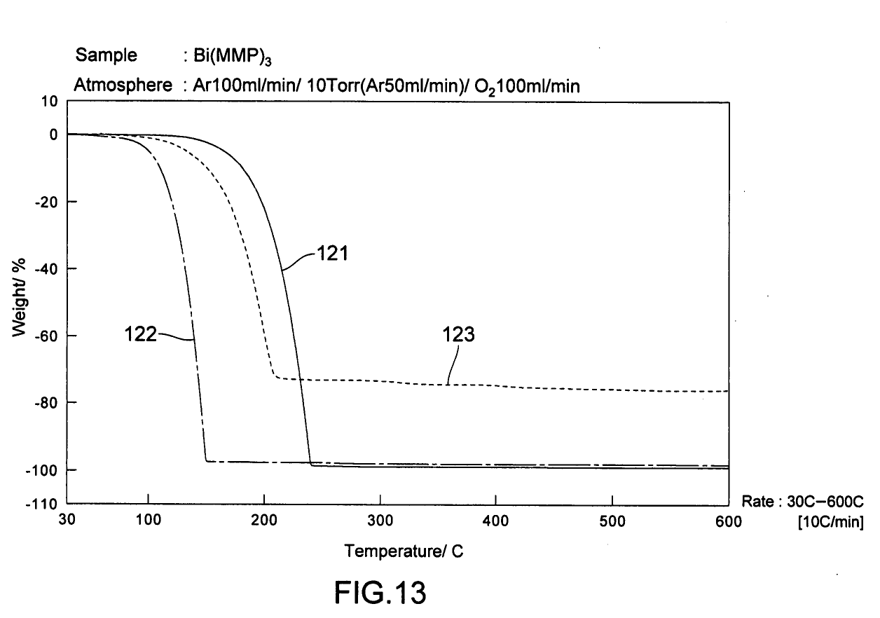

FIG. 14 is a TG CHART (Ar 760/10 Torr, O₂ 760 Toor) of a mixture of Bi(OtAm)₃/Sr[Ta(OEt)₆]₂;

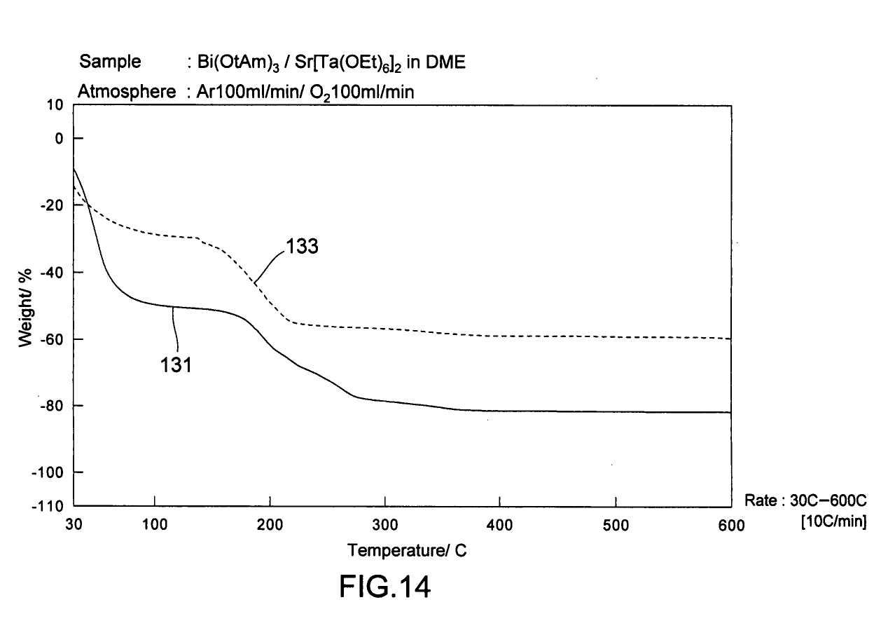

FIG. 15 a view illustrating NMR characteristic (nuclear magnetic resonance of H);

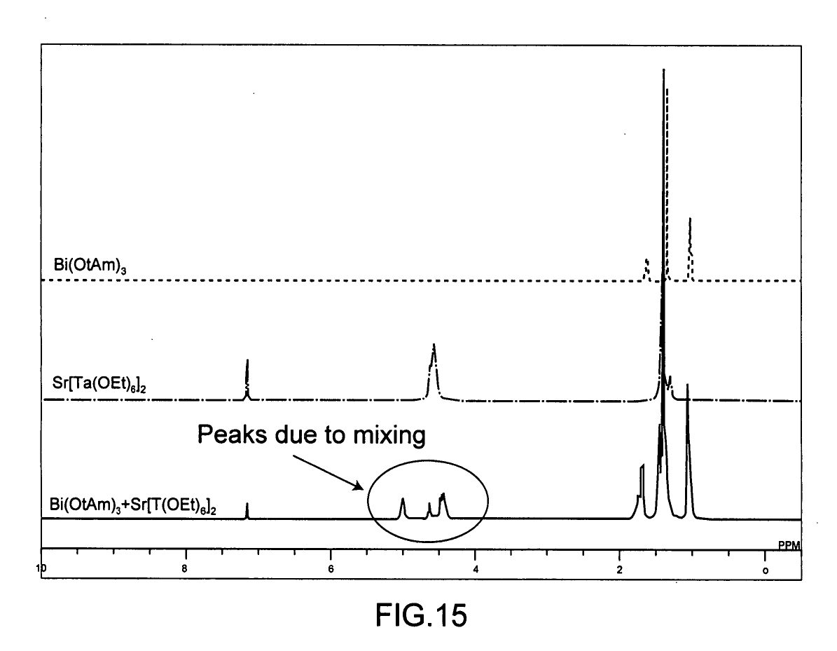

FIG. 16 is a TG CHART (Ar 760/10 Torr, O₂ 760 Toor) of a mixture of Bi(MMP)₃/Sr[Ta(OEt)₅(OC₂H₄OMe)]₂;

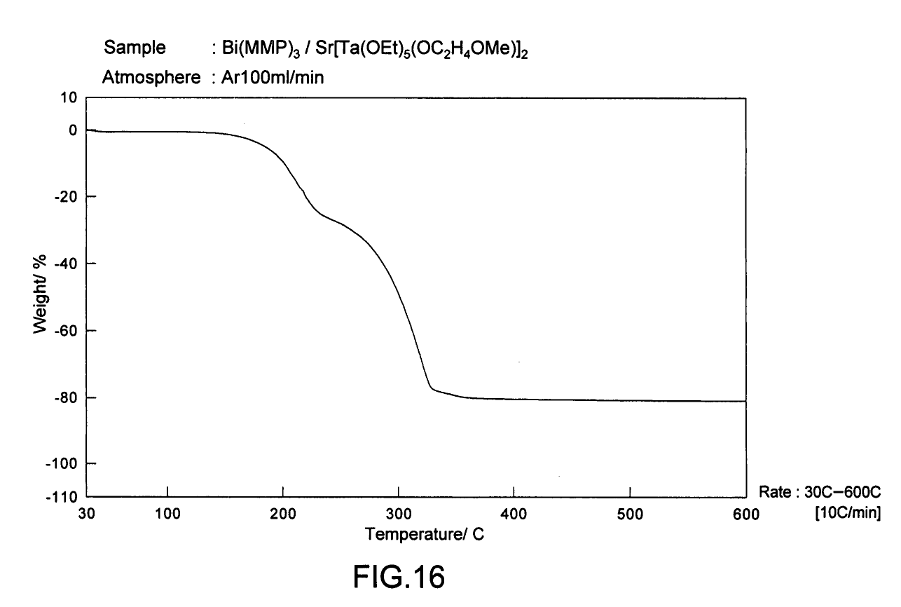

FIG. 17 is a TG CHART (Ar 760/10 Torr, O₂ 760 Toor) of BiPh₃;

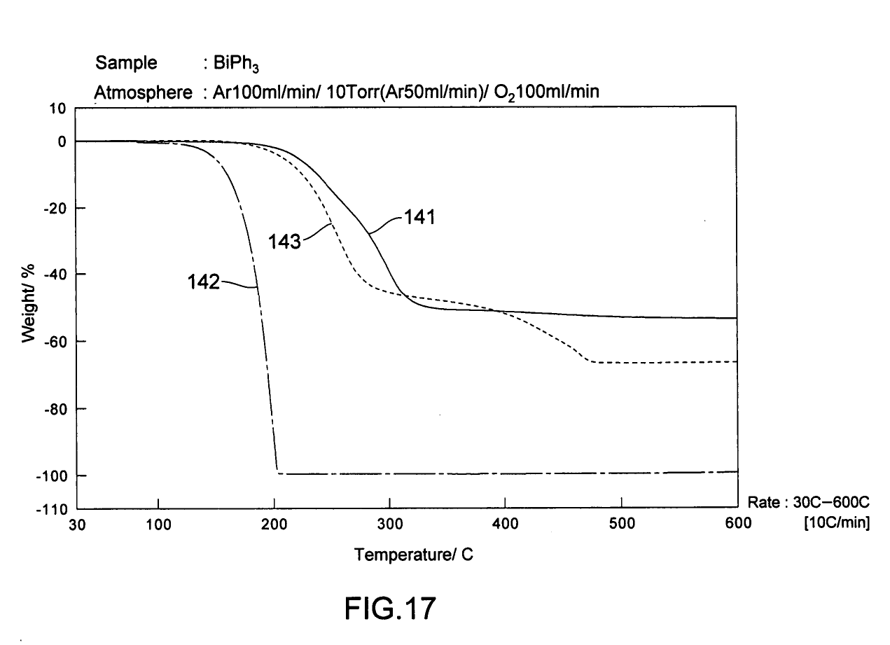

FIG. 18 is a TG CHART (Ar 760/10 Torr, O₂ 760 Toor) of BiPh₃/Sr[Ta(OEt)₆]₂;

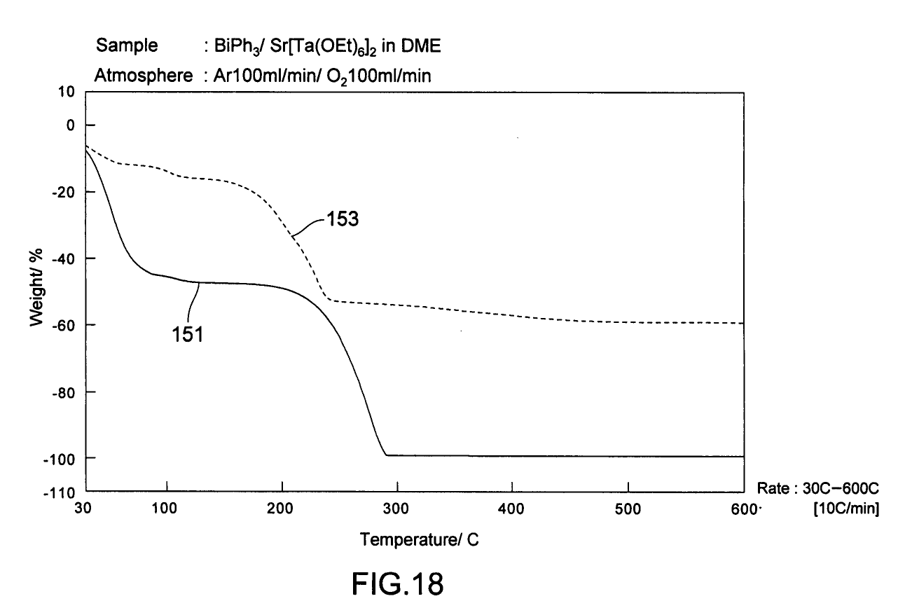

FIG. 19 is a view illustrating NMR characteristics representing stability of mixing BiPh₃ and Sr[Ta(OEt)₆]₂; and

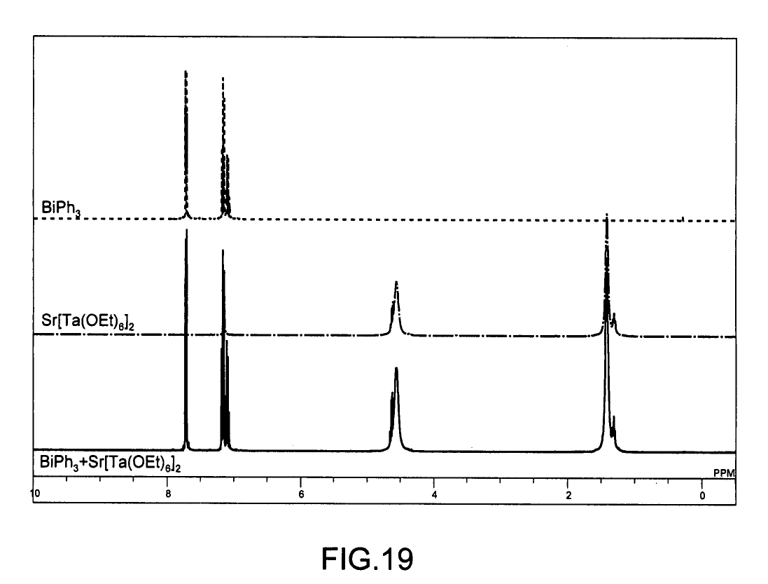

FIG. 20 is TG-DTA CHART (O₂ 760 Torr) of BiPh₃.

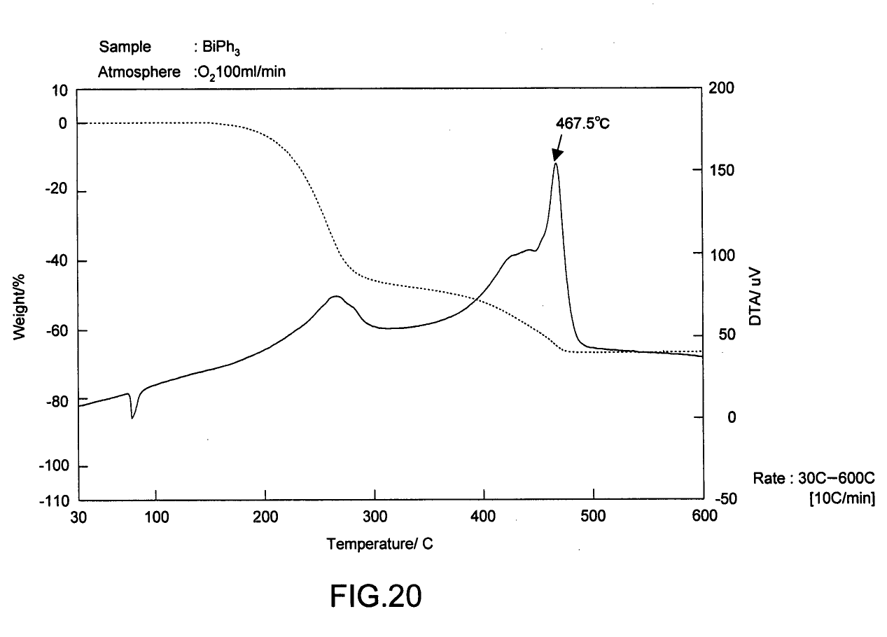

### DETAILED DESCRIPTION OF THE PREFERRED EMBODIMENTS

Preferred embodiments of the present invention will now be described with reference to the accompanying drawings.

### First Embodiment

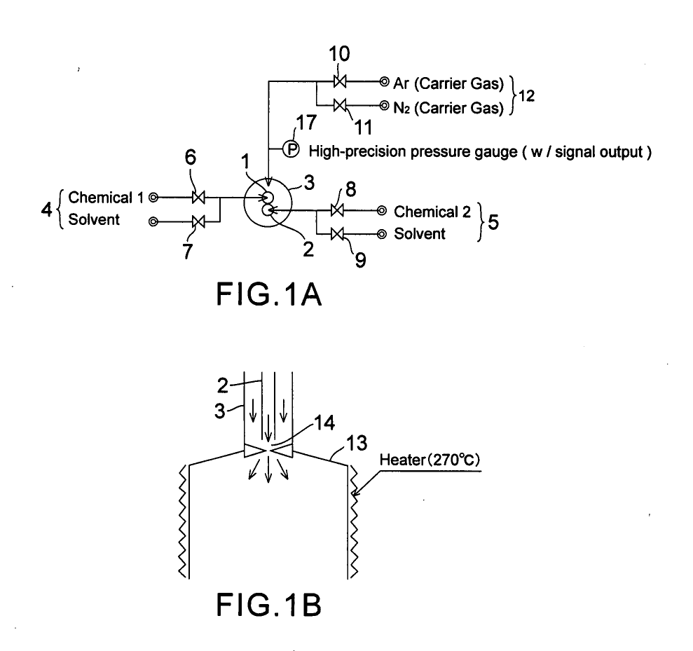

FIG. 1A is a schematic view illustrating a structure of a solution supplying system included in a vaporizer for CVD according to a first embodiment of the present invention, while FIG. 1B is a schematic cross sectional view illustrating the solution supplying system of the vaporizer, a dispersing portion thereof, and a vaporizing member thereof.

As illustrated in FIGS. 1A and 1B, the vaporizer for CVD has first and second pipes 1, 2 for raw-material solutions. The first pipe 1 is provided adjacent to the second pipe 2 in parallel therewith. A pipe 3 for a carrier gas is provided outwardly relative to the first and second pipes 1, 2. An internal diameter of the pipe 3 is formed to be larger than a sum of an external diameter of the first pipe 1 and that of the second pipe 2. The first and second pipes 1, 2 are inserted into the inside of the pipe 3, while the pipe 3 is formed in a manner containing the first and second pipes 1, 2 thereinside.

A base end of the first pipe 1 is connected to a first supplying mechanism 4 for supplying a chemical 1 and a solvent. The first supplying mechanism 4 has a chemical-supplying-source for supplying the chemical 1 (for instance, Sr[Ta(OEt)₅(OC₂H₄OMe)]₂), and a solvent-supplying-source for supplying the solvent. A valve 6 and a mass-flow controller (not illustrated) are provided in between the chemical-supplying-source and the first pipe 1. Moreover, a valve 7 and a mass-flow controller (not illustrated) are provided in between the solvent-supplying-source and the first pipe 1. The solvent and the chemical 1 flow into each other (mix) in between the solvent-supplying-source and the first pipe 1.

A base end of the second pipe 2 is connected to a second supplying mechanism 5 for supplying a chemical 2 and a solvent. The second supplying mechanism 5 has a chemical-supplying-source for supplying the chemical 2 (for instance, Bi(MMP)₃), and a solvent-supplying-source for supplying the solvent. A valve 8 and a mass-flow controller (not illustrated) are provided in between the chemical-supplying-source and the second pipe 2. Moreover, a valve 9 and a mass-flow controller (not illustrated) are provided in between the solvent-supplying-source and the second pipe 2. The solvent and the chemical 2 flow into each other (mix) in between the solvent-supplying-source and the second pipe 2.

A base end of the pipe 3 is connected to a third supplying mechanism 12 for supplying an argon gas and a nitrogen gas. The third supplying mechanism 12 has an argon-gas-supplying-source for supplying the argon gas (Ar), and a nitrogen-gas-supplying-source for supplying the nitrogen-gas (N₂). A valve 10 and a mass-flow controller (not illustrated) are provided in between the argon-gas-supplying-source and the pipe 3. Moreover, a valve 11 and a mass-flow controller (not illustrated) are provided in between the nitrogen-gas-supplying-source and the pipe 3. A high-precision pressure gauge 17 is provided in between the third supplying mechanism 12 and the pipe 3, while the high-precision pressure gauge 17 is one for constantly monitoring a pressure of the carrier gas in the inside of the pipe 3. The high-precision pressure gauge 17 sends an output signal to a non-illustrated controller. Based on the output signal, the pressure of the carrier gas can be displayed by a non-illustrated control-monitor and monitored.

A leading end of the pipe 3 is connected to one end of a vaporizing tube 13. An orifice is formed on the leading end of the pipe 3, while it allows the inside of the pipe 3 and that of the vaporizing tube 13 to be connected with each other. A heater is provided around the vaporizing tube 13, while the vaporizing tube 13 is heated at, for instance, 270° C. by the heater. The other end of the vaporizing tube 13 is connected to a non-illustrated reaction chamber.

Leading ends of the first and second pipes 1, 2 are spaced away from the orifice, respectively. A dispersing portion 14 is formed in between the respective leading ends of the first and second pipes 1, 2 in the inside of the pipe 3 and the orifice. The dispersing portion 14 mixes: a first raw-material solution (one made by mixing the chemical 1 and the solvent thereof) flows out of the leading end of the first pipe 1; a second raw-material solution (one made by mixing the chemical 2 and the solvent thereof) flows out of the leading end of the second pipe 2; and the argon or nitrogen gas flows out of the pipe 3, and then disperses the first and second raw-material solutions in the argon or nitrogen gas in fine particulate or misty forms.

Next, operations of the above vaporizer for CVD will now be explained in detail.

First, the valve 6 is opened so as to supply the first raw-material solution from the first supplying mechanism 4 to the first pipe 1 at predetermined flow rate and pressure. The first raw-material solution is, for instance, one made by mixing Sr[Ta(OEt)₅(OC₂H₄OMe)]₂ and the solvent thereof. Moreover, the valve 8 is opened so as to supply the second raw-material solution from the second supplying mechanism 5 to the second pipe 2 at predetermined flow rate and pressure. The second raw-material solution is, for instance, one made by mixing Bi(MMP)₃ and the solvent thereof. Further, the valves 10, 11 are opened so as to supply the carrier gas from the third supplying mechanism 12 to the pipe 3 at predetermined flow rate and pressure. The carrier gas is, for instance, the argon or nitrogen gas.

Next, the first raw-material solution is supplied to the dispersing portion 14 via the first pipe 1, the second raw-material solution is also supplied to the dispersing portion 14 via the second pipe 2, while the pressurized carrier gas is supplied to the dispersing portion 14 via the pipe 3. The dispersing portion 14 mixes the first raw-material solution, the second raw-material solution and the carrier gas, while it disperses the first and second raw-material solutions in the carrier gas in fine particulate or misty forms. It is preferable that the first and second raw-material solutions mixed by the dispersing portion 14 be dispersed in fine particulate or misty forms within a single second.

The first and second raw-material solutions dispersed in the carrier gas by the dispersing portion 14 are introduced into the vaporizing tube 13 via the orifice. In the vaporizing tube 13, the first and second raw-material solutions dispersed in misty forms are instantaneously heated at approximately 270° C. by the heater.

There is a large difference between a pressure of the inside of the dispersing portion 14 and that of the inside of the vaporizing tube 13. The inside of the vaporizing portion 13 is in a reduced pressure condition, while the dispersing portion 14 is in an increased pressure condition. The pressure of the inside of the vaporizing portion 13 is, for instance, 5-30 Torr, while that of the inside of the dispersing portion 14 is, for instance, 1500-2200 Torr. By setting the pressure-difference like this, the carrier gas is ejected toward the vaporizing tube 13 at ultrahigh-speed, and expands (for instance, adiabatic expansion) in accordance with the pressure-difference. Accordingly, a sublimation temperature of chemicals contained in the first and second raw-material solutions is dropped, and thus the raw-material solutions (with the chemicals) can be vaporized by the heat from the heater. Moreover, the first and second raw-material solutions are turned to be fine mist by the high-speed flow of the carrier gas immediately after dispersed by the dispersing portion 14, and thus they are easily vaporized instantaneously.

Thus way, a source gas is produced by vaporizing the first and second raw-material solutions in the vaporizer for CVD. The source gas is introduced into a reaction chamber via the vaporizing tube 13, while a thin film is deposited on a substrate to be processed by CVD.

As mentioned above, while vaporizing the raw-material solutions, the pressure of the carrier gas is constantly monitored by the high-precision pressure gauge 17. When the vaporizer for CVD is continuously operated, solutes of the raw-material solutions gradually precipitate on at least one of the dispersing portion 14 and the orifice, and thus the orifice (atomizing nozzle) is gradually clogged. The phenomenon is as follow.

When Sr[TA(OEt)₅(OC₂H₄OMe)]₂, Bi(MMP)₃, solutions (for instance, Ethyl CycloHexane:ECH) and the carrier gas (for instance, argon, nitrogen) are sprayed to the high-temperature vaporizing tube 13 under reduced-pressure atmosphere (approximately 5-30 Torr) so as to be atomized, some of the mist adhere to the atomizing nozzle and liquefy. In a solution adhering to the atomizing nozzle, only a solvent (for instance, Ethyl CycloHexane:ECH) having large vapor pressure is evaporated due to reduced-pressure atmosphere and the heat radiated from the vaporizing tube 13 in a high-temperature condition, solutes precipitate, and thus the atomizing nozzle is clogged.

As the clogging progressing, the pressure of the carrier gas in the inside of the pipe 3 increases. After the controller is notified by the high-precision pressure gauge 17 that the pressure of the carrier gas exceeds the predetermined value (for instance, 200 KPa) by receiving an output signal therefrom, the valves 6, 8 are closed so as to terminate the supply of the solutions of Sr[TA(OEt)₅(OC₂H₄OMe)]₂ and Bi(MMP)₃, while the valves 7, 9 are opened so as to allow only the solvents to flow. Or, an outlet of the vaporizing tube 13 is changed from a reactor to an exhaust portion (not illustrated), the solutions and the carrier gas are only supplied to the pipes 1 to 3 for cleaning. By increasing the volume of the flow of the solvents twice to ten times as much as that of the solutions, an effectiveness of the cleaning can be improved. Accordingly, the atomizing nozzle sprays the solvents, while the solutes precipitating thereon are re-dissolved by the solvents, whereby they are eliminated therefrom. Meanwhile, in this embodiment, the solvents for the cleaning are supplied from the first and second supplying mechanisms, but the supply thereof is not limited to this. For instance, a solvent supplying mechanism for the cleaning may be separately provided, while a solvent for the cleaning may be supplied from this solvent supplying mechanism. Moreover, it is preferable that the substrate to be processed be taken out from the reaction chamber prior to the cleaning, while a new substrate to be processed be put into the reaction chamber after the cleaning. When the solutes precipitate and adhere to the dispersing portion 14 or the like, lowering the sublimation rate of a CVD thin film and the change of the composition thereof are observed. As a result, a reproducibility of the CVD-thin-film deposition process, the quality thereof and the yield thereof are lowered. To prevent those lowering, it is preferable that the cleaning be carried out prior to the detection of the clogging. For instance, the reproducibility can be improved by cleaning the vaporizing tube 13 or the like during a period of a waiting time with a couple of minutes between one substrate is processed and the next CVD-thin-film-deposition process is performed with the next substrate being put into the reaction chamber.

During the above cleaning process, the pressure of the carrier gas in the pipe 3 is also monitored by the high-precision pressure gauge 17. Accordingly, a condition of the clogging of the orifice can be monitored. As the cleaning process continued, the clogging of the orifice (atomizing nozzle) can be gradually eliminated since the precipitated solutes are dissolved. Accordingly, the pressure of the carrier gas is lowered. After the controller is notified by the high-precision pressure gauge 17 that the pressure of the carrier gas is turned less than or equal to the predetermined value (for instance, 100 KPa) by receiving an output signal therefrom, the valves 6, 8 are re-opened so as to re-supply the raw-material solution.

Meanwhile, when the flow rate of one solution during the CVD process is Xcc/min., it is preferable that the capacities of the pipes from the valves 6 to 9 to the leading edges of the pipes 1, 2 be less than or equal to 8 Xcc, more preferably, less than or equal to 2 Xcc, and further preferably, less than or equal to Xcc.

Moreover, in this embodiment, the timing for the cleaning in order to eliminate the clogging of the atomizing nozzle with the solutions is determined by the high-precision pressure gauge 17 monitoring the pressure of the carrier gas, but not limited to this. For instance, the cleaning may be carried out by allowing the solutions and carrier gas to flow after predetermined times pass.

According to this embodiment, the orifice (atomizing nozzle) is cleaned by the solutions before it is completely clogged, and thus it can be brought into an original condition. Therefore, the vaporizer for CVD can be used for a significantly long time by performing the cleaning process during the operation thereof. It takes approximately 10 hours for disassembling the clogged vaporizer, cleaning and reassembling it. The above-described cleaning process, however, can be finished within a couple of minutes, and thus the operation time of the vaporizer can be considerably extended, while a production cost for a semiconductor device or the like can be considerably reduced.

Moreover, in this embodiment, the first and second pipes 1, 2 are provided adjacent to each other and in parallel with each other, while the pipe 3 for the carrier gas is provided outwardly relative to the first and second pipes 1, 2. Accordingly, the first raw-material solution (Sr[Ta(OEt)₅(OEtOMe)]₂) and the second raw-material solution (Bi(MMP)₃ can be separately supplied to the dispersing portion 14, whereby a chemical reaction of the first and second solutions in solution states does not occur, while the clogging in the inside of the pipe can be prevented. Therefore, the continuous operation time of the vaporizer for CVD can be extended.

Further, in this embodiment, the first and second pipes 1, 2 are contained in the pipe 3 having a larger diameter, the carrier gas is allowed to flow a space in between the first, second pipes 1, 2 and the pipe 3, while the vaporizing tube 13 is provided on a downstream side of the flow. Since the pressurized carrier gas is allowed to flow the space locating the outsides of the pipes 1, 2 at a high speed, a temperature rise in the first, second pipes 1, 2, the pipe 3 and the dispersing portion 14 can be suppressed. Accordingly, in the dispersing portion 14, a chemical reaction caused by the raw-material solutions can be suppressed since it is suppressed that only the solvents of the raw-material solutions vaporize, and thus the clogging of the dispersing portion 14 or the orifice can be suppressed. Therefore, the continuous operation time of the vaporizer for CVD can be extended.

Still further, in this embodiment, the first and second raw-material solutions are dispersed in fine particulate or misty forms immediately after mixed with the carrier gas by the dispersing portion 14 (within a single second). It is thus suppressed that only the solvents of the raw-material solutions vaporize. Accordingly, in the dispersing portion 14, a chemical reaction of the raw-material solutions by the dispersing portion 14 can be suppressed, and thus the clogging of the dispersing portion 14 or the orifice can be suppressed. Therefore, the continuous operation time of the vaporizer for CVD can be extended.

Moreover, according to this embodiment, the first and second raw-material solutions are dispersed by the dispersing portion 14, while the dispersed raw-material solutions in fine particulate or misty forms are heated in the inside of the vaporizing tube 13 so as to be vaporized (gasified) instantaneously. It is thus suppressed that only the solvent of the raw-material solutions vaporizes. Accordingly, in the orifice or the vaporizing tube 13 adjacent to the orifice, a chemical reaction of the raw-material solutions can be suppressed, and thus the clogging of the orifice or the vaporizing tube 13 can be suppressed. Therefore, the continuous operation time of the vaporizer for CVD can be extended.

As described, according to this embodiment, the clogging of the pipes 1 to 3, the dispersing portion 14, the orifice and the vaporizing tube 13 can be prevented, and even if they are clogged, the cleaning is carried out for bringing them into the original conditions. Accordingly, the vaporizer for CVD can be continuously operated for long time. Therefore, a thin film of a ferroelectric material such as PZT, SBT or the like can be deposited with good reproducibility and controllability, while the vaporizer and the solution-vaporization CVD of high performance can be embodied.

As described above, even if the high-precision pressure gauge 17 is provided for monitoring the condition of the clogging, the cleaning process is required, and thus the vaporizer can not be completely continuously operated. Accordingly, when one reaction chamber is equipped with a plurality of vaporizers each having the cleaning mechanism, a solution-vaporization CVD apparatus which can continuously deposit over several hundred hours can be embodied. To be more precise, for instance, a reaction chamber is equipped with 12 vaporizers each having the cleaning mechanism, and during the operation of the solution-vaporization CVD apparatus, two vaporizers among them are cleaned, while other 10 vaporizers are continuously operated. Accordingly, a continuous operation of a solution-vaporization CVD apparatus over several hundred hours can be carried out, while a deposition rate of thin film can be remarkably improved. The solution-vaporization CVD apparatus, which sequentially cleans at least one of the vaporizers so as to carry out a continuous deposition, is suitable for a case that, for instance, YBCO of a superconductive oxide thin film with a thickness of 10 μm is formed on a substrate having an extremely long tape shape.

### Second Embodiment

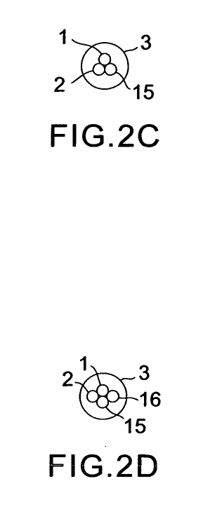

FIG. 2C is a schematic view illustrating a structure of a solution supplying system included in a vaporizer for CVD according to a second embodiment of the present invention. The same structure portions as those illustrated in FIG. 1A will be denoted the same reference numbers, respectively, while detailed explanations thereof will be omitted.

The vaporizer for CVD illustrated in FIG. 2C has three pipes 1, 2 and 15 for supplying three kinds of raw-material solutions, respectively. The first pipe 1, the second pipe 2 and the third pipe 15 are provided adjacent to one another and in parallel with one another. The pipe 3 for a carrier gas is provided outwardly relative to the first to third pipes 1, 2 and 15. The first to third pipes 1, 2 and 15 are inserted into the inside of the pipe 3, while the pipe 3 is formed in a manner containing the first to third pipes 1, 2 and 15 thereinside.

A base end of the third pipe 15 is connected to a third supplying mechanism (not illustrated) for supplying a chemical 3 and a solvent. The third supplying mechanism has a chemical-supplying-source for supplying the chemical 3, and a solvent-supplying-source for supplying the solvent. A valve (not illustrated) and a mass-flow controller (not illustrated) are provided in between the chemical-supplying-source and the third pipe 15. Moreover, a valve (not illustrated) and a mass-flow controller (not illustrated) are provided in between the solvent-supplying-source and the third pipe 15. The solvent and the chemical 3 flow into each other (mix) in between the solvent-supplying-source and the third pipe 15.

Leading ends of the first to third pipes 1, 2 and 15 are spaced away from the orifice, respectively. A dispersing portion is formed in between the respective leading ends of the first to third pipes 1, 2 and 15 in the inside of the pipe 3 and the orifice. The dispersing portion mixes: a first raw-material solution (one made by mixing the chemical 1 and the solvent thereof) flows out of the leading end of the first pipe 1; a second raw-material solution (one made by mixing the chemical 2 and the solvent thereof) flows out of the leading end of the second pipe 2; a third raw-material solution (one made by mixing the chemical 3 and the solvent thereof) flows out of the leading end of the third pipe 15; and the argon or nitrogen gas flows out of the pipe 3, and then disperses the first to third raw-material solutions into the argon or nitrogen gas in fine particulate or misty forms.

According to the second embodiment, the same advantageous effect as that of the first embodiment can be obtained.

### Third Embodiment

FIG. 2D is a schematic view illustrating a structure of a solution supplying system included in a vaporizer for CVD according to a third embodiment of the present invention. The same structure portions as those illustrated in FIG. 2C will be denoted the same reference numbers, respectively, while detailed explanations thereof will be omitted.

The vaporizer for CVD illustrated in FIG. 2D has four pipes 1, 2, 15 and 16 for supplying four kinds of raw-material solutions. The first pipe 1, the second pipe 2, the third pipe 15 and the fourth pipe 16 are provided adjacent to one another and in parallel with one another. The pipe 3 for a carrier gas is provided outwardly relative to the first to fourth pipes 1, 2, 15 and 16. The first to fourth pipes 1, 2, 15 and 16 are inserted into the inside of the pipe 3, while the pipe 3 is formed in a manner containing the first to fourth pipes 1, 2, 15 and 16 thereinside.

A base end of the fourth pipe 16 is connected to a fourth supplying mechanism (not illustrated) for supplying a chemical 4 and a solvent. The fourth supplying mechanism has a chemical-supplying-source for supplying the chemical 4, and a solvent-supplying-source for supplying the solvent. A valve (not illustrated) and a mass-flow controller (not illustrated) are provided in between the chemical-supplying-source and the fourth pipe 16. Moreover, a valve (not illustrated) and a mass-flow controller (not illustrated) are provided in between the solvent-supplying-source and the fourth pipe 16. The solvent and the chemical 4 flow into each other (mix) in between the solvent-supplying-source and the fourth pipe 16.

Leading ends of the first to fourth pipes 1, 2, 15 and 16 are spaced away from the orifice, respectively. A dispersing portion is formed in between the respective leading ends of the first to fourth pipes 1, 2, 15 and 16 in the inside of the pipe 3 and the orifice. The dispersing portion mixes: a first raw-material solution (one made by mixing the chemical 1 and the solvent thereof) flows out of the leading end of the first pipe 1; a second raw-material solution (one made by mixing the chemical 2 and the solvent thereof) flows out of the leading end of the second pipe 2; a third raw-material solution (one made by mixing the chemical 3 and the solvent thereof) flows out of the leading end of the third pipe 15; a fourth raw-material solution (one made by mixing the chemical 4 and the solvent thereof) flows out of the leading end of the fourth pipe 16; and the argon or nitrogen gas flows out of the pipe 3, and then disperses the first to fourth raw-material solutions in the argon or nitrogen gas in fine particulate or misty forms.

According to the third embodiment, the same advantageous effect as that of the second embodiment can be obtained.

The present invention is not limited to the above embodiments, various embodiments and changes may be made thereonto without departing from the broad spirit and scope of the invention. For instance, the vaporizer, the vaporization method for CVD and the CVD apparatus according to the present invention can be applied variously, not only they are applied to the formation of a high-quality ferroelectric thin film (for instance, SBT, PZT) for a FeRAM-LSI as a ferroelectric memory, but also the formation of other films such as YBCO (super conductive oxide), thick PZT/PLZT/SBT film(for filter, MEMS, optical interconnect, HD), metal film (Ir, Pt, Cu), barrier metal (TiN, TaN), high k film(HfOx, Al₂O₃, BST or the like) with various kinds of chemicals used, for instance, a material having low vapor pressure.

Moreover, in the above embodiments, the first raw-material solution is made by dissolving Sr[Ta(OEt)₅(OC₂H₄OMe)]₂ in the solution thereof, while the second raw-material solution is made by dissolving Bi(MMP)₃ in the solution thereof, but the raw-material solution is not limited to those. For instance, a raw-material solution may be made by dissolving the other kind of a solid material in a solution thereof. Further, a liquid material of Sr[Ta(OEt)₅(OC₂H₄OMe)]₂ or the like itself may be used as a raw-material solution, while one made by mixing a liquid material with a solution may be used.

Further, in the above embodiments, one kind of a thin film is formed on a substrate to be processed, respectively. However, plural kinds of thin films may be successively formed on a substrate. To be more precise, a raw-material solution and a carrier gas are allowed to flow into the reaction chamber (CVD chamber) via the vaporizing tube for CVD for an appropriate period so as to form a first thin film on a substrate. Next, a valve for the raw-material solution is changed to be as an exhaust, while another kind of raw-material solution is supplied to the reaction chamber via the vaporizing tube at a predetermined flow rate. When a sum of the flow rate of this raw-material solution (that is, volume thereof) exceeds one to five times of a capacity of a pipe from the valve to the reaction chamber, this raw-material solution and a carrier gas are allowed to flow into the reaction chamber via the vaporizing tube for an appropriate period so as to form a second thin film on the substrate. Accordingly, two kinds of thin films having different compositions can be successively formed. Moreover, by repeating this process, three or more kinds of thin films can be formed. Meanwhile, when supplying another kind of raw-material solution to the reaction chamber, a temperature of the substrate and a pressure when reacting may be appropriately changed.

### EXAMPLE

An example according to the present invention will now be explained.

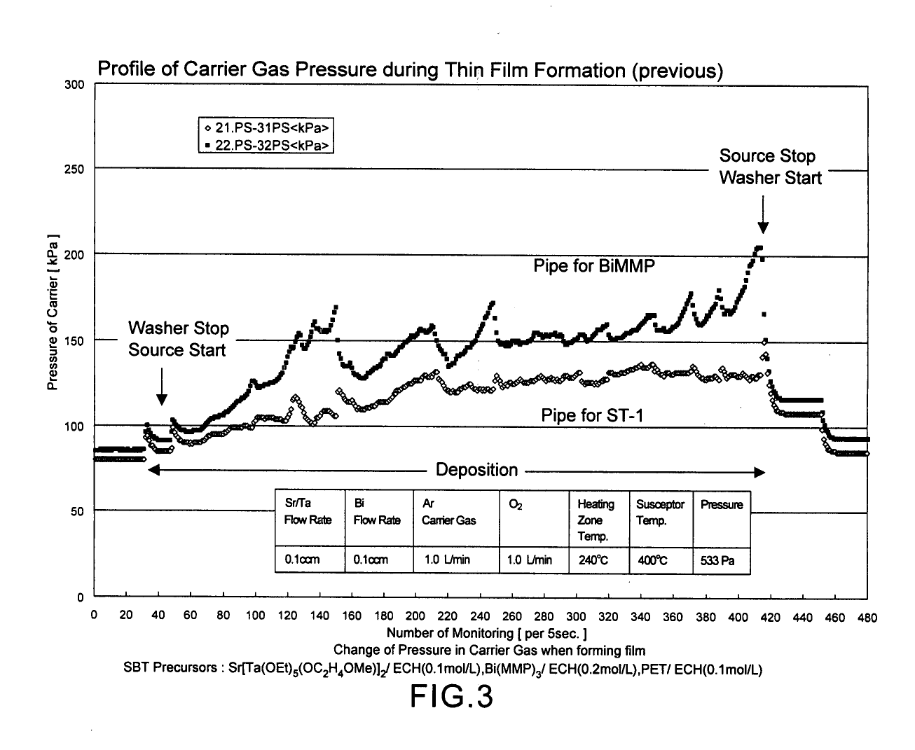

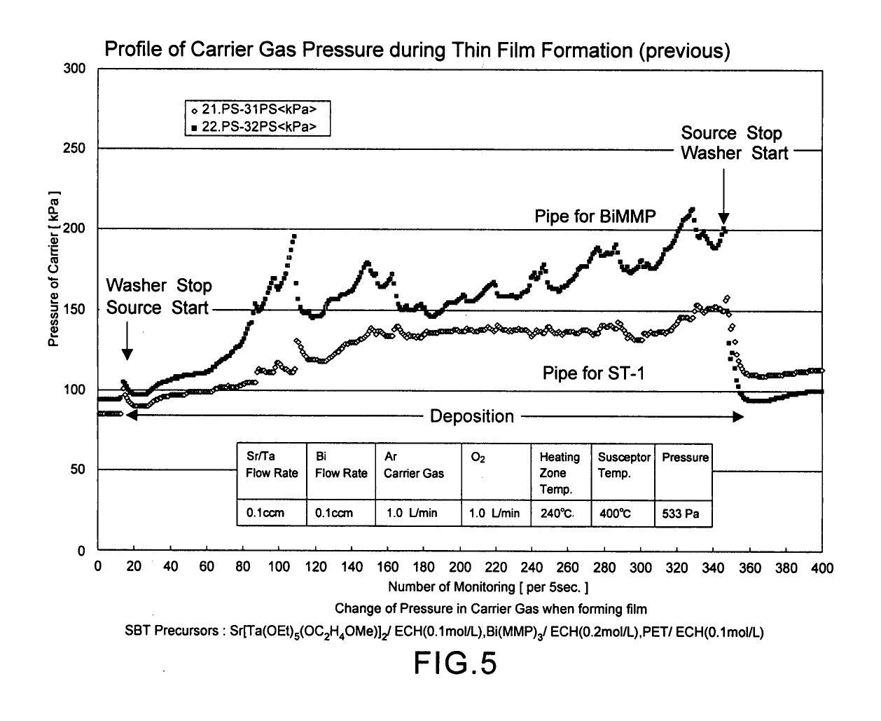

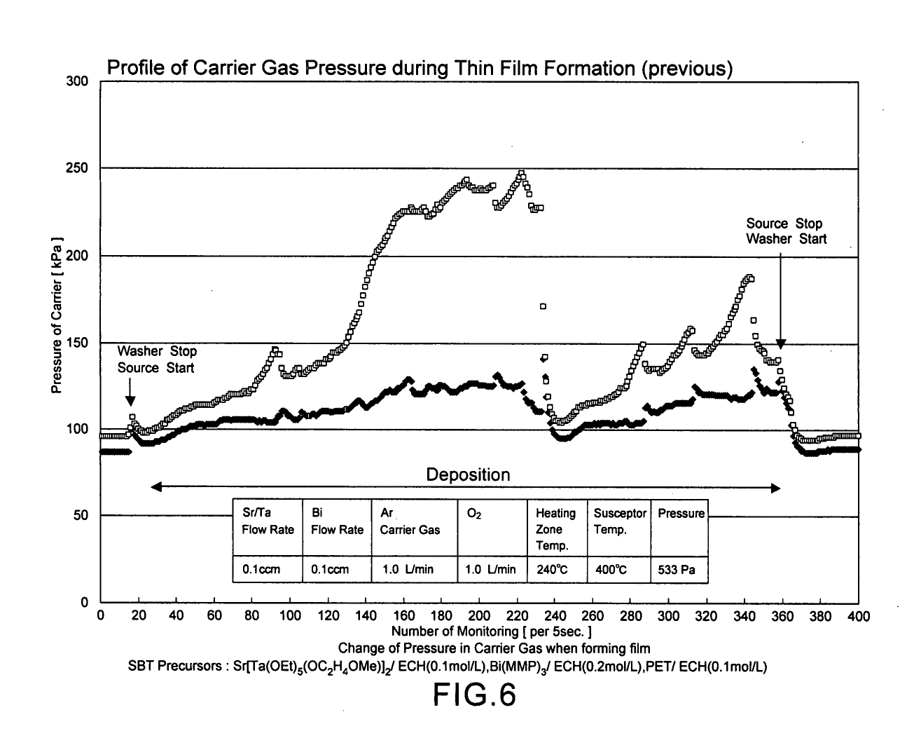

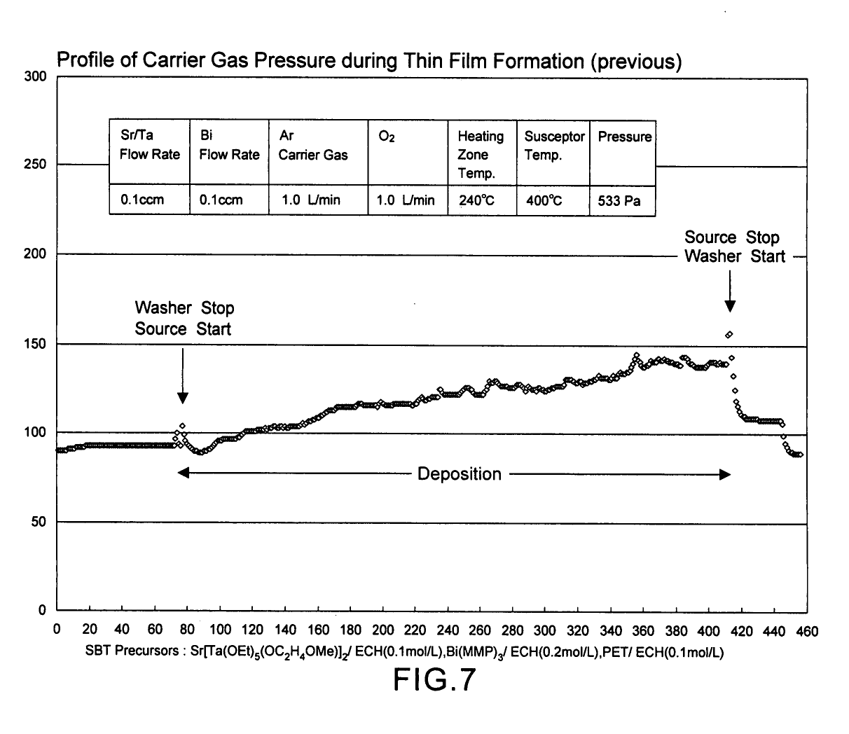

Resultants of monitoring the pressures of the carrier gas are illustrated in FIGS. 3 to 8. As illustrated in FIG. 3, at a monitor point 80, when chemicals were started to flow into the vaporizing tube 13, the pressure of the carrier gas gradually increased. At a monitor point 420, the pressure of the BiMMP carrier gas reached to 220 kPa (approximately 2.2 barometric pressure (gage pressure)). At this point, the supply of BiMMP (0.2 ccm) was terminated, while a cleaning solvent ECH (0.5 ccm) was allowed to flow. Accordingly, the pressure of the carrier gas rapidly fell and stabilized at a monitor point 440. The pressure-fall thereof indicated that BiMMP adhered to the atomizing nozzle (orifice) was eliminated.

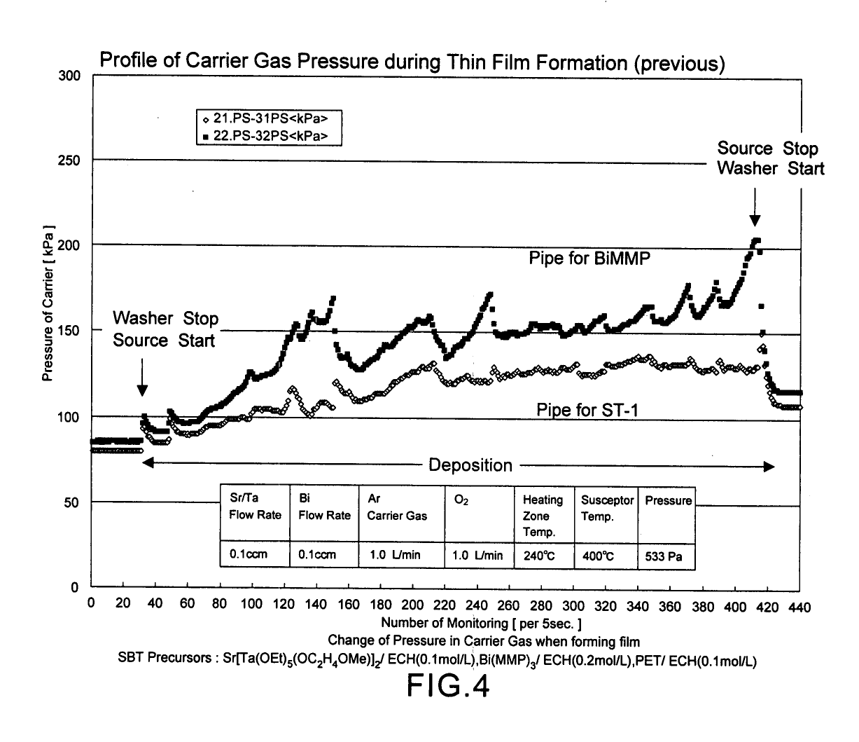

As illustrated in FIGS. 4 to 6, similar to the case of FIG. 3, the phenomenon of the adhesion with respect to the atomizing nozzle occurred with good reproducibility. The phenomenon was observed not only in a SBT-CVD process with Sr[Ta(OEt)₅(OC₂H₄OMe)]₂ and Bi(MMP)₃ used, but also in other SBT-CVD processes with the following chemicals used: Pb(DPM)₂/ECH (0.15 mol/L); Zr(DIBM)₄/ECH (0.15 mol/L); and Ti(Oi-Pr)₂(DPM)₂/ECH (0.30 mol/L).

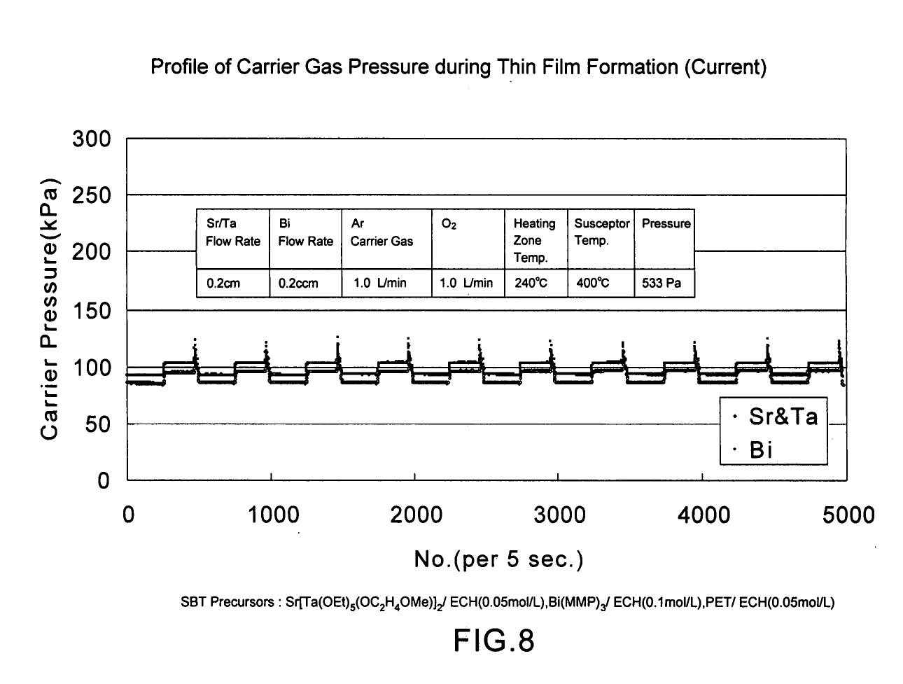

In the case illustrated in FIG. 8, a change of the pressure in the carrier gas was small. Because the densities of the solutions of Sr[Ta(OEt)₅(OC₂H₄OMe)]₂ and Bi(MMP)₃ were diluted by ½, the progress of the clogging at the atomizing nozzle was declined. In this case, a pressure increase in the carrier gas was not observed during an approximately 40 minute SBT thin film deposition. Moreover, by performing a cleaning process with respect to each deposition, a SBT-CVD process was carried out in a condition that no clogging occurred

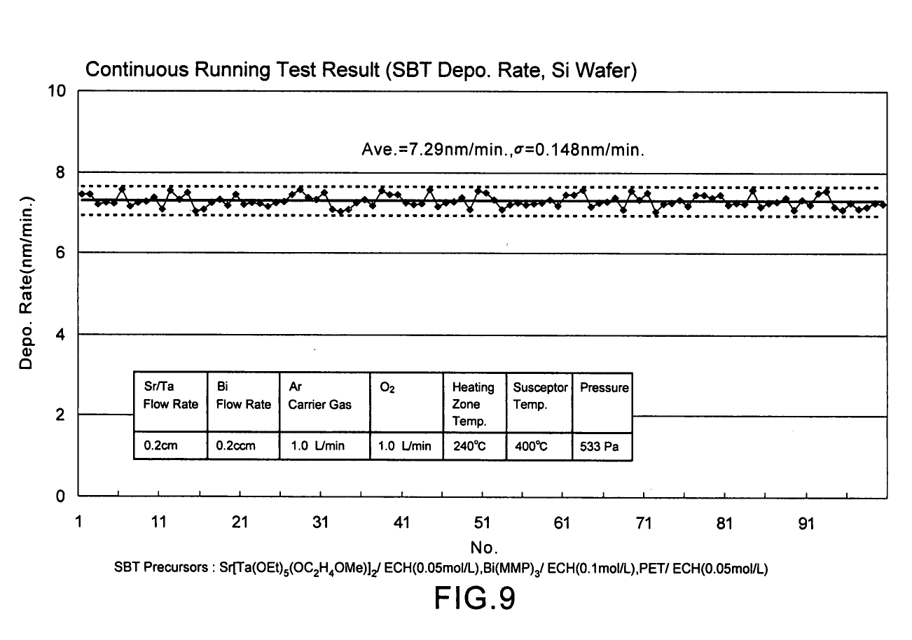

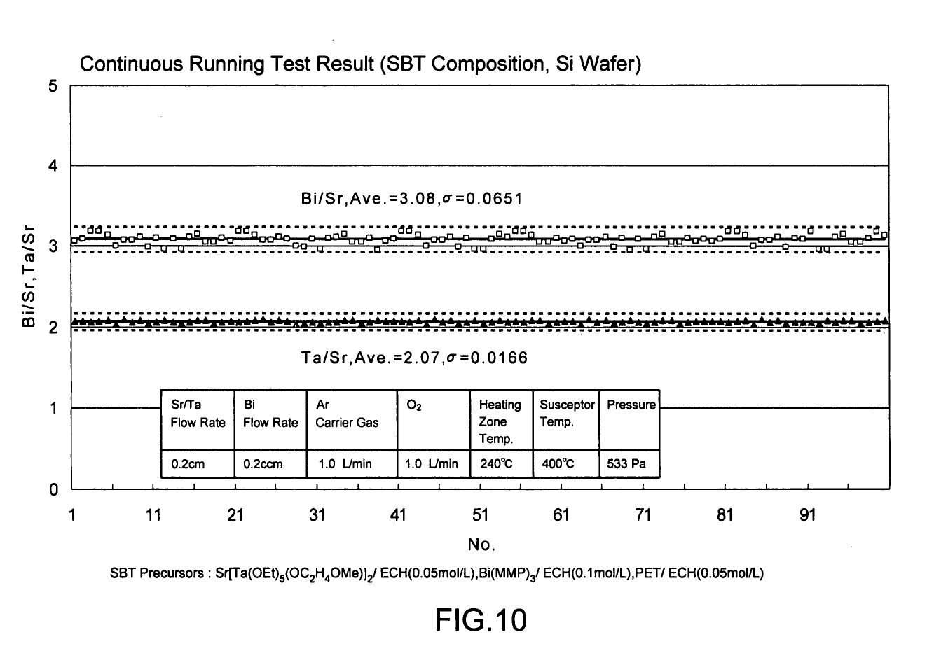

FIGS. 9 and 10 illustrate resultants of a reproducibility experiment of SBT-CVD with the vaporizer of the present invention used.

FIG. 9 illustrates reproducibility of deposition rate. A deposition-rate experiment with 100 batches was performed, while the average deposition rate was 7.29 nm/min., σ=0.148 nm/min., and thus a good continuous deposition and a good reproducibility were achieved.

FIG. 10 illustrates reproducibility of film composition. A deposition-rate experiment with 100 batches was performed, while the average relative proportion of Bi/Sr was 3.08, σ=0.065, and thus the good reproducibility was achieved. Moreover, the average relative proportion of Ta/Sr was 2.07, σ=0.0166, and thus a good continuous deposition was achieved.

1-14. (canceled)

15. A vaporizer for CVD comprising:
a dispersing portion dispersing a plurality of raw-material solutions in a carrier gas in fine particulate or misty forms;
a plurality of paths for the plurality of raw-material solutions, each of said plurality of paths supplying the plurality of raw-material solutions to said dispersing portion separately from one another;
a path for the carrier gas, said path supplying the carrier gas to said dispersing portion separately from the plurality of raw-material solutions;
a vaporizing member vaporizing the plurality of raw-material solutions dispersed by said dispersing portion;
an orifice connected to said vaporizing member and said dispersing portion, said orifice introducing the plurality of raw-material solutions dispersed by said dispersing portion into said vaporizing member; and
a cleaning mechanism cleaning at least one of said dispersing portion, said orifice and said vaporizing member.

16. The vaporizer for CVD according to claim 15, further comprising a reaction chamber connected to said vaporizer to form a solution-vaporization CVD apparatus.

17. The vaporizer for CVD according to claim 15, further comprising a monitoring mechanism for monitoring a pressure of the carrier gas.

18. The vaporizer for CVD according to claim 17, further comprising a reaction chamber connected to said vaporizer to form a solution-vaporization CVD apparatus.

19. A vaporizer for CVD comprising:
a dispersing portion dispersing a plurality of raw-material solutions in a carrier gas in fine particulate or misty forms;
a plurality of paths for the plurality of raw-material solutions, each of said plurality of paths supplying the plurality of raw-material solutions to said dispersing portion separately from one another;
a path for the carrier gas, said path supplying the carrier gas to said dispersing portion separately from the plurality of raw-material solutions;
a monitoring mechanism for monitoring a pressure of the carrier gas;
a vaporizing member vaporizing the plurality of raw-material solutions dispersed by said dispersing portion; and
an orifice connected to said vaporizing member and said dispersing portion, said orifice introducing the plurality of raw-material solutions dispersed by said dispersing portion into said vaporizing member.

20. The vaporizer for CVD according to claim 19, further comprising a reaction chamber connected to said vaporizer to form a solution-vaporization CVD apparatus.

21. A vaporizer for CVD comprising:
a plurality of pipes for a plurality of raw-material solutions, each of said plurality of pipes supplying the plurality of raw-material solutions separately from one another;
a pipe for a carrier gas, said pipe being provided in a manner covering outwards of said plurality of pipes, while said pipe allowing the carrier gas, said carrier gas being pressurized, to flow thereinside and the outward of each of said plurality of pipes;
an orifice provided on a leading end of said pipe for the carrier gas, said orifice being spaced away from leading ends of said plurality of pipes for the plurality of raw-material solutions;
a vaporizing tube connected to said leading end of said pipe for the carrier gas, said vaporizing tube being connected to the inside of said pipe for the carrier gas via said orifice;
a cleaning mechanism cleaning at least one of said leading end of said pipe for the carrier gas, said orifice, said vaporizing tube; and
a heating means for heating said vaporizing tube.

22. The vaporizer for CVD according to claim 21, further comprising a reaction chamber connected to said vaporizer to form a solution-vaporization CVD apparatus.

23. The vaporizer for CVD according to claim 22, wherein a deposition is carried out with the plurality of raw-material solutions used, the plurality of raw-material solutions being vaporized by said vaporizing tube.

24. The solution-vaporization CVD apparatus according to claim 23, wherein:
the solution-vaporization CVD apparatus is equipped with a plurality of vaporizers for CVD; and
some of said plurality of vaporizers for CVD are respectively in a cleaned condition cleaned by said cleaning mechanism, while others thereof are respectively in operated conditions; and
the plurality of vaporized raw-material solutions are continuously supplied to said reaction chamber by swapping said plurality of vaporizers for CVD in the operated conditions for those in the cleaned conditions as time advances.

25. The vaporizer for CVD according to claim 21, further comprising a monitoring mechanism for monitoring a pressure of the carrier gas in an inside of said pipe for the carrier gas.

26. The vaporizer for CVD according to claim 25, wherein said cleaning mechanism cleans said leading end of said pipe for the carrier gas and said orifice by supplying at least a solution thereto.

27. The vaporizer for CVD according to claim 26, further comprising a reaction chamber connected to said vaporizer to form a solution-vaporization CVD apparatus, and wherein a deposition is carried out with the plurality of raw-material solutions used, the plurality of raw-material solutions being vaporized by said vaporizing tube.

28. The solution-vaporization CVD apparatus according to claim 27, wherein:
the solution-vaporization CVD apparatus is equipped with a plurality of vaporizers for CVD; and
some of said plurality of vaporizers for CVD are respectively in a cleaned condition cleaned by said cleaning mechanism, while others thereof are respectively in operated conditions; and
the plurality of vaporized raw-material solutions are continuously supplied to said reaction chamber by swapping said plurality of vaporizers for CVD in the operated conditions for those in the cleaned conditions as time advances.

29. The vaporizer for CVD according to claim 25, further comprising a reaction chamber connected to said vaporizer to form a solution-vaporization CVD apparatus.

30. The vaporizer for CVD according to claim 29, further comprising a reaction chamber connected to said vaporizer to form a solution-vaporization CVD apparatus, and
wherein a deposition is carried out with the plurality of raw-material solutions used, the plurality of raw-material solutions being vaporized by said vaporizing tube.

31. The solution-vaporization CVD apparatus according to claim 30 wherein:
the solution-vaporization CVD apparatus is equipped with a plurality of vaporizers for CVD; and
some of said plurality of vaporizers for CVD are respectively in a cleaned condition cleaned by said cleaning mechanism, while others thereof are respectively in operated conditions; and
the plurality of vaporized raw-material solutions are continuously supplied to said reaction chamber by swapping said plurality of vaporizers for CVD in the operated conditions for those in the cleaned conditions as time advances.

32. The vaporizer for CVD according to claim 21, wherein said cleaning mechanism cleans said leading end of said pipe for the carrier gas and said orifice by supplying at least a solution thereto.

33. The vaporizer for CVD according to claim 32, further comprising a reaction chamber connected to said vaporizer to form a solution-vaporization CVD apparatus.

34. The vaporizer for CVD according to claim 33, wherein a deposition is carried out with the plurality of raw-material solutions used, the plurality of raw-material solutions being vaporized by said vaporizing tube.

35. The solution-vaporization CVD apparatus according to claim 34, wherein:
the solution-vaporization CVD apparatus is equipped with a plurality of vaporizers for CVD; and
some of said plurality of vaporizers for CVD are respectively in a cleaned condition cleaned by said cleaning mechanism, while others thereof are respectively in operated conditions; and
the plurality of vaporized raw-material solutions are continuously supplied to said reaction chamber by swapping said plurality of vaporizers for CVD in the operated conditions for those in the cleaned conditions as time advances.

36. A vaporization method for CVD comprising:
supplying a plurality of raw-material solutions and a carrier gas to a dispersing portion separately from one another;
mixing the plurality of raw-material solutions and the carrier gas by the dispersing portion and dispersing the plurality of raw-material solutions in the carrier gas in fine particulate or misty forms;
vaporizing the raw-material solutions by adiabatic expansion immediately after dispersing; and
cleaning at least one of the dispersing portion and an area for vaporizing the raw-material solutions.

37. A vaporization method for CVD, comprising:
supplying a plurality of raw-material solutions and a carrier gas to a dispersing portion separately from one another;
mixing the plurality of raw-material solutions and the carrier gas by the dispersing portion, and dispersing the plurality of raw-material solutions in the carrier gas in fine particulate or misty forms;
vaporizing the raw-material solutions by adiabatic expansion immediately after dispersing;
monitoring a pressure of the carrier gas while vaporizing the raw-material solutions, and terminating the supply of the raw-material solutions to the dispersing portion upon observing that the pressure of the carrier gas exceeds a predetermined value;
and cleaning at least one of the dispersing portion and an area for vaporizing the plurality of raw-material solutions.

38. The vaporization method for CVD according to claim 37, wherein a solvent for cleaning and solvents contained in the plurality of raw-material solutions are homogeneous.

39. The vaporization method for CVD according to claim 38, wherein:
said process for cleaning is one for cleaning at least one of the dispersing portion and the area for vaporizing the plurality of raw-material solutions by supplying a solvent and the carrier gas thereto; and
the pressure of the carrier gas is monitored during said process for cleaning so that the supply of the solvent is terminated upon observing that the pressure of the carrier gas is turned less than or equal to the predetermined value so as to terminate said process for cleaning.

40. The vaporization method for CVD according to claim 37, wherein a solvent for cleaning and solvents contained in the plurality of raw-material solutions are homogeneous.
